(19) United States
(12) Patent Application Publication
(10) Pub. No.: US 2015/0244397 A1
(43) Pub. Date: Aug. 27, 2015

(54) Method Of Efficient FEC Decoder Scheduling And Receiver Pipeline Flow Control And Apparatus Using The Same

(71) Applicant: Metanoia Communications Inc., Hsinchu (TW)

(72) Inventor: Terry Cris Brown, Austin, TX (US)

(73) Assignee: Metanoia Communications Inc., Hsinchu (TW)

(21) Appl. No.: 14/190,480

(22) Filed: Feb. 26, 2014

(51) Int. Cl. H03M 13/11; H03M 13/00

(52) U.S. Cl. CPC H03M 13/1145; H03M 13/6561

(57) ABSTRACT

Various embodiments of a technique of efficient FEC decoder scheduling and receive pipeline flow control are provided. In one aspect, a method may involve a communication device receiving a frame. The method may also involve the method processing the frame. In processing the frame, the method may involve the communication device dynamically adjusting allocation of time for decoding each codeword in the frame by a decoder of the communication device.

### TECHNICAL FIELD

The present disclosure relates to the field of digital communications and, more particularly, to efficient FEC decoder scheduling and receiver pipeline flow control in digital communication systems.

### BACKGROUND

Communication systems such as G.hn (ITU-T standard G.9960/G.9961) rely on low density parity check (LDPC) codes for forward error correction (FEC). These codes have recently become popular in several advanced communication systems because they can lead to a throughput that approaches the channel capacity of a channel while still allowing for efficient decoding. The decoding methods used for these codes are usually based on iterative techniques that converge on the correct codeword after some number of iterations when the channel noise is not too high. Since it is generally not possible to know when the noise level has exceeded the capability of the code to correct the errors, it is not easy to determine if a particular LDPC decoding iteration would converge and find the correct codeword. Ideally a decoder in a receiver of a communication system is allowed to run decoder iterations until the codeword is successfully recovered or it is determined that convergence is unlikely. However, that is not practical for high data-rate communications since the upper limit on the decoding time is unknown. Therefore, decoders are typically designed with sufficient throughput to run a fixed number of iterations for each codeword. If it takes the decoder longer than this upper limit to converge to a correct codeword, the decoder aborts the operation and the codeword is uncorrected. If the decoder converges in fewer number of iterations than the maximum number of iterations, the decoder moves on to the next codeword, but there is no way to take advantage of the time savings. Therefore, it is desirable to have a technique that provides the maximum amount of time to the decoder for decoding each codeword, based on the time budget available in the receiver at any given instant.

The receiver time budget for G.hn as well as other communication systems depends on several factors. Generally, a receiver is designed with a throughput that matches or exceeds the requirements of the relevant standard. In the case of G.hn the throughput target is 1 Gbps for a 100-Mhz baseband power-line device. Since the receiver pipeline dataflow is complex, each component of the pipeline needs to exceed this throughput requirement so that the overall pipeline can meet the requirement. Another consideration for the pipeline is the inter-frame gap (IFG) which defines the minimum amount of time between transmissions on the medium. In a half-duplex system such as G.hn, the size of the IFG determines how quickly the receiver pipeline must complete the processing of a frame before preparing to transmit the next frame. Since the LDPC decoder is the last part of the G.hn pipeline, the IFG affects the amount of time the LDPC decoder can spend working on the final codewords of a frame. The location of the LDPC decoder in the pipeline also means that it can slow down the entire pipeline if it consumes too much time. A receiver pipeline would usually include a time domain first-in-first-out (FIFO) module that can absorb some extra pipeline delay caused by the LDPC decoder or other receiver processes. The size of this FIFO module also affects the time budget of the receiver pipeline in general and the LDPC decoder in particular.

### SUMMARY

Various embodiments pertaining to efficient FEC decoder scheduling and receiver pipeline flow control are described herein. Embodiments of the techniques, processes, algorithms, devices, apparatuses and systems described herein, and any variations thereof, may be implemented in the form of software, firmware, hardware or any combination thereof.

According to one aspect, a method may include: receiving, by a communication device, a frame; and processing the frame by the communication device. The processing may include dynamically adjusting allocation of time for decoding each codeword in the frame by a decoder of the communication device.

In one embodiment, the dynamically adjusting allocation of time for decoding each codeword in the frame may include: calculating an average amount of time that can be allowed by the decoder in decoding each codeword, a minimum amount of time that must be allowed by the decoder in decoding each codeword, and a maximum amount of time that cannot be exceeded by the decoder in decoding each codeword.

In one embodiment, the dynamically adjusting allocation of time for decoding each codeword in the frame may further include: tracking, during processing of the frame, a number of codewords processed by the decoder, and a target number of codewords that would be processed if the average codeword processing time were maintained.

In one embodiment, the dynamically adjusting allocation of time for decoding each codeword in the frame may further include: determining whether the number of codewords processed by the decoder is above the target number of codewords.

In one embodiment, the dynamically adjusting allocation of time for decoding each codeword in the frame may further include: in response to determining that the number of codewords processed by the decoder is above the target number of codewords, determining whether an amount of time used by the decoder in decoding a current codeword equals a maximum amount of time that cannot be exceeded by the decoder in decoding each codeword.

In one embodiment, the dynamically adjusting allocation of time for decoding each codeword in the frame may further include: in response to determining that the amount of time used by the decoder in decoding a current codeword has reached the maximum amount of time: abandoning the current codeword; and processing a next codeword in the frame.

In one embodiment, the dynamically adjusting allocation of time for decoding each codeword in the frame may further include: in response to determining that the amount of time used by the decoder in decoding the current codeword has not reached the maximum amount of time and enough time remains to run a decoder iteration, enabling the decoder to perform a next iteration on the current codeword.

In one embodiment, the dynamically adjusting allocation of time for decoding each codeword in the frame may further include: in response to determining that the number of codewords processed by the decoder is not above the target number of codewords, determining whether there is sufficient extra time to allow for one or more additional iterations by the decoder for the current codeword.

In one embodiment, the determining whether there is sufficient extra time may include: tracking an amount of extra time to allow for one or more additional iterations by the decoder for each codeword based at least in part on a number of clocks per iteration for decoding a codeword of a given size and a clock counter used in tracking the slack.

In one embodiment, the dynamically adjusting allocation of time for decoding each codeword in the frame may further include: in response to determining that there is sufficient extra time to allow for one or more additional iterations by the decoder for the first codeword, determining whether the time used by the decoder in decoding the current codeword equals the maximum amount of time that cannot be exceeded by the decoder in decoding each codeword.

In one embodiment, the dynamically adjusting allocation of time for decoding each codeword in the frame may further include: in response to determining that the time used by the decoder in decoding the current codeword has reached the maximum amount of time, abandoning the current codeword and processing a next codeword in the frame.

In one embodiment, the dynamically adjusting allocation of time for decoding each codeword in the frame may further include: in response to determining that the amount of time used by the decoder in decoding a current codeword has not reached the maximum allowed time, enabling the decoder to perform a next iteration on the current codeword.

In one embodiment, the dynamically adjusting allocation of time for decoding each codeword in the frame may further include: in response to determining that there is not sufficient extra time to allow for one or more additional iterations by the decoder for the current codeword, determining whether a minimum amount of time has been consumed by the decoder in decoding the current codeword.

In one embodiment, the dynamically adjusting allocation of time for decoding each codeword in the frame may further include: in response to determining that the minimum amount of time has been consumed by the decoder in decoding the current codeword, abandoning the current codeword and processing a next codeword in the frame.

In one embodiment, the dynamically adjusting allocation of time for decoding each codeword in the frame may further include: in response to determining that the minimum amount of time has not been consumed by the decoder in decoding the first codeword, enabling the decoder to perform a next iteration on the first codeword.

In one embodiment, the decoder may include a low density parity check (LDPC) decoder.

In one embodiment, a decoder time may be tracked based on iterations of the LDPC decoder.

In one embodiment, the average, minimum, and maximum times may be recalculated at some points during processing of the frame.

According to another aspect, a device may include: a memory unit configured to store data, a set of instructions, or a combination thereof; a communication unit configured to receive a frame; and a processing unit coupled to the memory unit and the communication unit. The processing unit may be configured to process the frame by dynamically adjusting allocation of time for decoding each codeword in the frame.

In one embodiment, in dynamically adjusting allocation of time for decoding each codeword in the frame, the processing unit may be configured to perform operations including: calculating an average amount of time that can be allowed by the processing unit in decoding each codeword, a minimum amount of time that must be allowed by the processing unit in decoding each codeword, and a maximum amount of time that cannot be exceeded by the processing unit in decoding each codeword; tracking, during processing of the frame, a number of codewords processed by the processing unit and a target number of codewords that would be processed if the average codeword processing time were maintained; and determining whether the number of codewords processed by the processing unit is above the target number of codewords.

In one embodiment, in dynamically adjusting allocation of time for decoding each codeword in the frame, the processing unit may be further configured to perform operations including: in response to determining that the number of codewords processed by the decoder is above the target number of codewords, determining whether an amount of time used by the processing unit in decoding a current codeword equals a maximum amount of time that cannot be exceeded by the processing unit in decoding each codeword; in response to determining that the amount of time used by the processing unit in decoding a current codeword has reached the maximum amount of time: abandoning the current codeword; and processing a next codeword in the frame; in response to determining that the amount of time used by the decoder in decoding the current codeword has not reached the maximum amount of time and enough time remains to run a decoder iteration, enabling the processing unit to perform a next iteration on the current codeword.

In one embodiment, in dynamically adjusting allocation of time for decoding each codeword in the frame, the processing unit may be further configured to perform operations including: in response to determining that the number of codewords processed by the processing unit is not above the target number of codewords, determining whether there is sufficient extra time to allow for one or more additional iterations by the processing unit for the current codeword; tracking an amount of extra time to allow for one or more additional iterations by the processing unit for each codeword based at least in part on a number of clocks per iteration for decoding a codeword of a given size and a clock counter used in tracking the extra time; in response to determining that there is sufficient extra time to allow for one or more additional iterations by the processing unit for the current codeword, determining whether the time used by the processing unit in decoding the current codeword equals the maximum amount of time that cannot be exceeded by the processing unit in decoding each codeword; in response to determining that the time used by the processing unit in decoding the current codeword has reached the maximum amount of time: abandoning the current codeword; and processing a next codeword in the frame; in response to determining that the time used by the processing unit in decoding the current codeword has not reached the maximum amount of time, performing a next iteration on the current codeword; in response to determining that there is not sufficient extra time to allow for one or more additional iterations by the processing unit for the current codeword, determining whether a minimum number of iterations has been performed by the processing unit in decoding the first codeword; in response to determining that the minimum amount of time has been consumed by the processing unit in decoding the current codeword: abandoning the current codeword; and processing a next codeword in the frame; and in response to determining that the minimum amount of time has not been consumed by the processing unit in decoding the current codeword, performing a next iteration on the current codeword.

This summary is provided to introduce the inventive concept pertaining to efficient FEC decoder scheduling and receiver pipeline flow control in digital communication systems. A select number of embodiments, including preferred embodiments, of the inventive concept are further described below in the detailed description. This summary is not intended to identify essential features of the claimed subject matter, nor is it intended for use in determining the scope of the claimed subject matter.

### BRIEF DESCRIPTION OF THE DRAWINGS

The accompanying drawings are included to provide a further understanding of the disclosure, and are incorporated in and constitute a part of the present disclosure. The drawings illustrate embodiments of the disclosure and, together with the description, serve to explain the principles of the present disclosure.

FIG. 1 is a block diagram of an example transceiver that implements a technique of efficient FEC decoder scheduling and receiver flow pipeline control in accordance with an embodiment of the present disclosure.

FIG. 2 is a timing diagram of a receiver flow pipeline in accordance with an embodiment of the present disclosure.

FIG. 3 is a flowchart of a process of an algorithm of efficient FEC decoder scheduling and receiver flow pipeline control in accordance with an embodiment of the present disclosure.

FIG. 4 is a flowchart of a process of codeword selection pertaining to efficient FEC decoder scheduling and receiver flow pipeline control in accordance with an embodiment of the present disclosure.

FIG. 5 is a flowchart of a process of counter update pertaining to efficient FEC decoder scheduling and receiver flow pipeline control in accordance with an embodiment of the present disclosure.

FIG. 6 is a flowchart of a process of efficient FEC decoder scheduling and receiver flow pipeline control in accordance with an embodiment of the present disclosure.

FIG. 7 is a device configured to perform efficient FEC decoder scheduling and receiver flow pipeline control in accordance with an embodiment of the present disclosure.

### DETAILED DESCRIPTION OF PREFERRED EMBODIMENTS

### Overview

The inventive concept presented herein takes into account in real-time all of the factors described above with respect to the issues to be addressed to produce a maximum number of iterations allowed for each codeword in the decoder. Therefore, each codeword gets the maximum amount of processing time and has a greater chance of convergence, leading to overall improvement in the throughput as well as reduction in the number of uncorrected codewords that need to be retransmitted.

The basic strategy of the inventive concept is to calculate the target number of iterations that can be allowed, on average, for each codeword in a frame and then ensure that this target is met, for the duration of the frame. The target is tracked and compared to the actual progress in order to allow additional time to be allocated to codewords when the LDPC decoder progress is faster than average. In this manner each codeword is allocated the maximum amount of time and the pipeline timing constraints are not exceeded. Those of ordinary skill in the art would appreciate that, although examples and embodiments presented herein are specific to G.hn, the inventive concept is applicable to any communication system that uses LDPC or similar error correcting codes which take variable time for decoding depending on the noise conditions on the channel.

### Example Transceiver and Operations Thereof

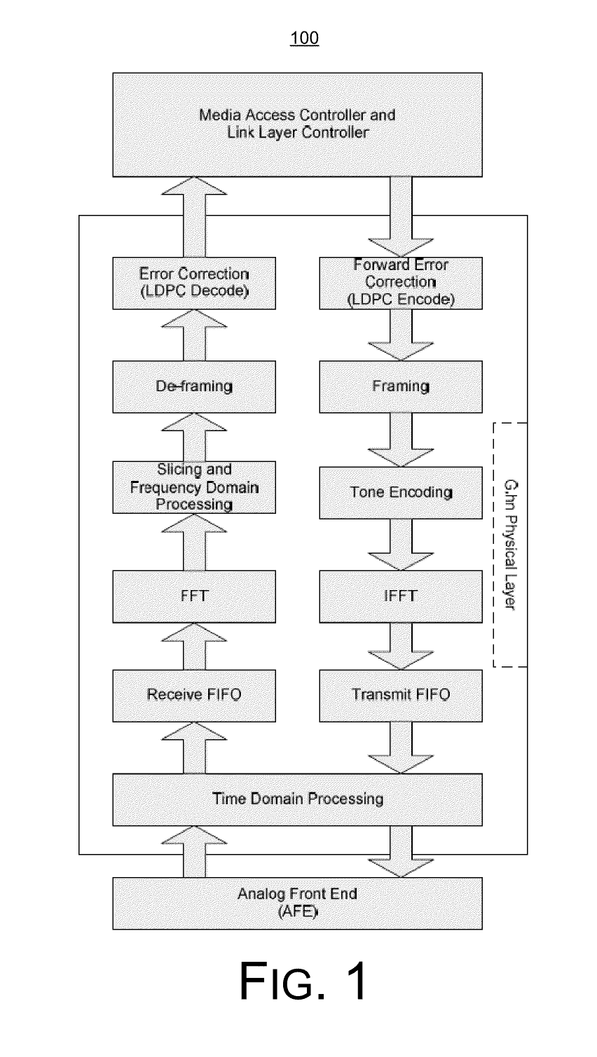

FIG. 1 illustrates a block diagram of an example transceiver 100 that implements a technique of efficient FEC decoder scheduling and receiver flow pipeline control in accordance with an embodiment of the present disclosure.

Referring to FIG. 1, the downward-pointing arrows indicate the transmit direction and the upward-pointing arrows indicate the receive direction in the transceiver 100. The inventive concept largely deals with controlling the processing of the LDPC decoder block in the receive path in order to provide maximum possible processing time for decoding each codeword of a received frame. Each of the functional blocks depicted in FIG. 1 represents a certain function carried out by the transceiver 100. Although the functional blocks are shown as discrete blocks, the functions of some or all of the functional blocks may be physically implemented in a single piece of hardware such as an integrated circuit (IC) chip for example. That is, the transceiver 100 may be implemented in one or more chips, chipset and/or circuit board, or a device having the same. Moreover, the function of each functional block, as well as the functions of some or all of the functional blocks, may be implemented in the form of software, firmware, hardware or any combination thereof.

In the receive direction, samples enter from the analog front end (AFE) block at the rate of one sample per sample clock and are processed in the time domain by the time domain processing block. The FIFO block collects samples and kicks off the fast Fourier transform (FFT) block whenever an entire orthogonal frequency division multiplexing (OFDM) symbol's worth of samples are available for processing. The time domain samples of the OFDM symbol are then processed in the FFT block and transferred to the frequency domain processing block. Similar to the FFT block, the frequency domain processing block processes data on OFDM symbol boundaries. After the frequency domain processing, the data is segregated (using the operation known as de-framing) along the codeword boundaries into FEC codewords for processing in the error correction block (i.e., LDPC decoder). The three distinct processing granularities along the receive path (namely: sample, symbol, and codeword) make pipeline dataflow scheduling complex. This is further complicated by the fact that the relative time required for each process varies depending on the parameters chosen for the frame (e.g., bit loading, codeword size, FEC rate, etc). With the exception of the error correction, all processes in the receive path usually take a constant amount of time for a particular frame with a given set of framing parameters. However, the time taken by the LDPC decoder is variable and depends on the noise conditions on the channel. The focus of the inventive concept is to carefully control the variable processing time of the LDPC decoder to ensure efficient receiver operation in spite of the complex dataflow requirements.

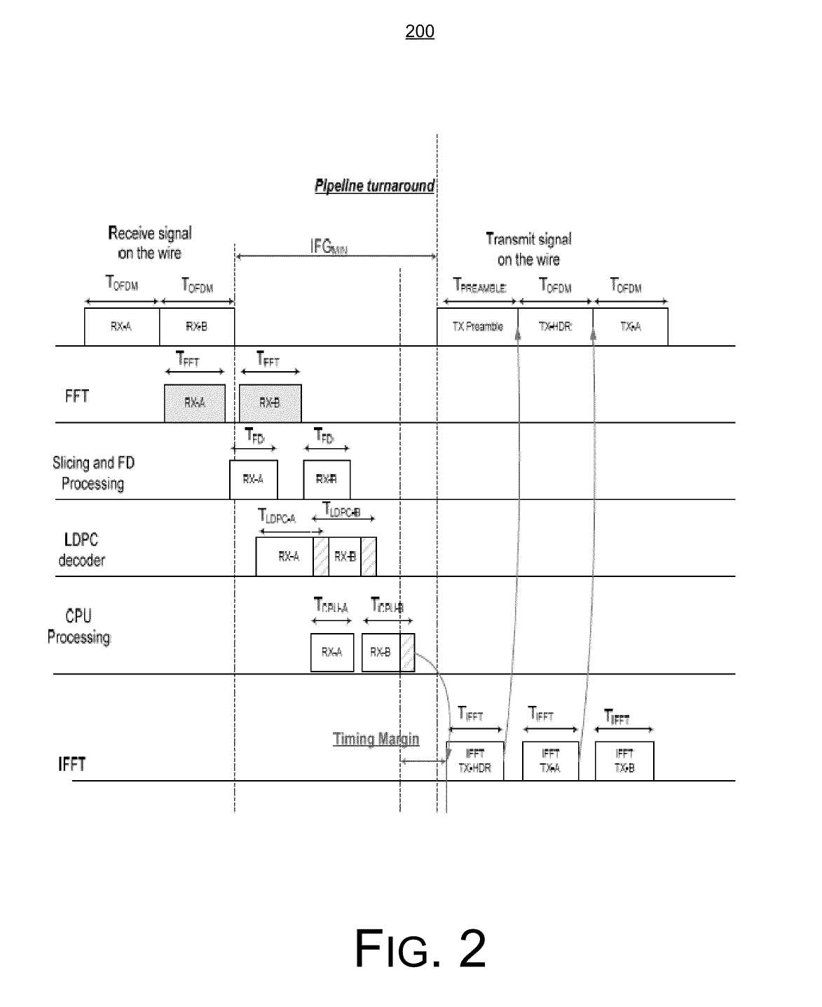

FIG. 2 illustrates a timing diagram 200 of a receiver flow pipeline in accordance with an embodiment of the present disclosure.

For a half-duplex system such as G.hn, one of the considerations for allocating time to the LDPC decoder is the maximum time allowed between receiving a frame and transmitting a new frame, known as the inter-frame gap (IFG). The IFG affects the decoder time budget when an immediate response (either as an acknowledgement or a new transmission) is required after a frame is received. FIG. 2 illustrates how the LDPC decoder timing affects the pipeline timing and also how it depends on the IFG. As shown in FIG. 2, the time allocated to the LDPC decoder for the last codewords directly consumes some portion of the available IFG time.

Referring to FIG. 2, the diagram 200 illustrates the data dependencies for the receive (RX) and transmit (TX) pipelines. Each stage of the receive pipeline depends on the one before in order to supply data. For instance, the FFT block cannot start on a particular symbol of data until the entire symbol is received. Likewise, the slicing and frequency domain processing block cannot start until the FFT block has completed processing the entire symbol. It is possible that the LDPC decoder can start before the frequency domain processing is completed since the LDPC decoder works on LDPC codewords rather than entire symbols. Embodiments of the inventive concept is applicable in both of the following scenarios:
1) where the LDPC decoder starts processing as soon as a codeword is available; and
2) where the LDPC decoder waits for the frequency domain processing to be completed before it starts processing the LDPC codewords.

The example illustrated in FIG. 2 is for the case where the received data needs to be processed by a processor, e.g., a central processing unit (CPU) of a transceiver such as transceiver 100 for example, in order to generate a quick response (e.g., G.hn immediate acknowledgment). Therefore, there is a data dependency between the data received in the current frame and the data to be transmitted in the next frame. This is indicated by the curved arrow. Data processing needs to be completed by the LDPC decoder and the CPU before the TX-HDR symbol can be generated for transmission on the transmission medium. Usually, the transmit preamble does not depend on the received data. Therefore, it may be possible to start the transmission of the preamble before the transmit data is prepared. This is shown in diagram 200 since the TX preamble overlaps in time with the IFFT TX-HDR. Based on diagram 200, the IFG can be met if the following simplified equation (Equation 1) is true:

(T_{FFT}+T_{FD}+T_{LDPC}+T_{CPU}+T_{IFFT})<(IFG_{MIN}+T_{PREAMBLE}) (1)

In Equation 1 all the time values are constant for a given set of framing parameters with the exception of T_{LDPC} (available time for processing by the LDPC decoder) and T_{CPU} (available time for processing by the CPU). Therefore, when the goal is to increase T_{CPU} (available time for processing by the CPU) or decrease IFG_{MIN} (minimum required time for IFG), thereby improving the throughput by reducing the wasted time on the transmission medium, the goal may be accomplished by reducing T_{LDPC}. The time budget established by the inventive concept allows an upper limit to be placed on T_{LDPC} while still providing maximum processing time for each codeword in the LDPC decoder.

### Example Algorithm

An example algorithm of efficient FEC decoder scheduling and receive pipeline flow control in accordance with the present disclosure is described herein.

The example algorithm may be explained by way of equations expressed in terms of parameters and variables. Definitions of certain parameters used in the algorithm, calculated for each received frame, are as follows:
CL_{CW}—Average number of clocks allowed for processing per codeword
I_{MIN}—Minimum number of iterations allowed to run per codeword
I_{MAX}—Maximum number of iterations allowed to run per codeword
CL_{I}—The number of clocks per iteration for processing the given codeword size
I_{Slack}—Maximum number of additional iterations allowed above average
CL_{Slack}—Maximum number of additional clocks allowed above average
CL_{INIT}—Initial number of additional clocks allowed above I_{MIN}

Definitions of certain working variables used in the algorithm, calculated for each received frame, are as follows:
CW_{CUR}—The current processed codeword count
CW_{AVE}—The average number of codewords that should have been processed, based on CL_{CW}
I_{CUR}—The current LDPC iteration number for the codeword being processed
CNT_{AVE}—The clock counter used to track the target average, CW_{AVE}
CNT_{Slack}—The clock counter used to track the slack

It is noteworthy that, although the definitions and algorithm description are defined in terms of system clocks, any time measuring mechanism with sufficient resolution would suffice.

For G.hn most of the parameters for a frame that is being received are unknown until the header has been decoded. Therefore, the example algorithm described herein is applied to the payload of the frame, after the header has been successfully decoded.

After the header has been decoded, the following basic parameters for the frame may be determined:
CL_{SYM}—The number of clocks per OFDM symbol, based on the symbol rate
SYM_{SIZE}—The number of bits transmitted in each symbol, based on the selected bit allocation table (BAT)
CW_{SIZE}—The size of the codeword in bits
SYM_{TOT}—The total number of payload symbols in the frame

Using these parameters the CL_{CW} parameter may be calculated as follows (Equation 2):

CL_{CW}=(CL_{SYM}*CW_{SIZE})/SYM_{SIZE} (2)

This calculation is simplified for illustrative purposes. The last OFDM symbol could contain a partial codeword that does not need to be processed. In very low throughput cases the difference could be significant. However, in those cases the LDPC decoder has more time to work on each codeword and the difference may not need to be considered.

As long as the LDPC decoder runtime per codeword is less than or equal to CL_{CW}, the decoder would not slow down the receiver pipeline. However, for the purpose of maximizing decoding efficiency it is advantageous to sometimes allow the decoder to exceed this average (CL_{CW}). The amount of additional time the decoder is allowed to consume, referred to as the slack herein, is largely determined by two factors, namely: (1) the amount of additional space in the receive FIFO, and (2) the required IFG. For a frame that does not require a quick response the available FIFO space would determine the slack and the IFG would not be a consideration. However, if a quick response is required (such as G.hn acknowledgement) then it is possible that the FIFO cannot be allowed to fill up without potentially exceeding the IFG. Since the slack represents time, it can be specified in terms of number of clocks as follows (Equation 3):

CL_{Slack}=min(available RX FIFO space in system clocks,IFG time budget) (3)

Equation 3 is merely a guideline as the actual calculation may need to consider other factors related to the receiver pipeline dataflow or system timing. For hardware efficiency the slack can also be specified in terms of the number of decoder iterations, as long as each iteration requires a fixed number of clocks, as follows (Equation 4):

I_{Slack}=floor(CL_{Slack}/CL_{I}) (4)

The algorithm requires two additional tuning parameters, namely: I_{MIN} and I_{MAX}. The minimum number of iterations allowed per codeword would normally be set to a maximum number of iterations that can be run without exceeding CL_{CW}, as follows (Equation 5):

I_{MIN}=floor(CL_{CW}/CL_{I}) (5)

Since the I_{MIN} calculation could drop too much precision in some cases, an initial slack could be assigned to compensate using the CL_{INIT} parameter. For example, this parameter could be set to the total precision loss due to rounding: CL_{INIT}=(CL_{CW} mod CL_{I})*(total number of OFDM symbols in the frame), provided that CL_{INIT}<=CL_{Slack}. The I_{MIN} parameter could also be set lower than the above calculation to allow the decoder to catch up after falling behind. In that case the algorithm would perform better on the initial codewords if it were initialized with more slack assigned in CL_{INIT}. Although the I_{MIN} parameter specifies the minimum number of iterations to run, the LDPC decoder could decide to abandon the codeword before I_{MIN} iterations if the LDPC decoder determines that the codeword is unlikely to converge based on some other criteria. The LDPC decoder could also successfully decode the codeword in fewer iterations.

The other tuning parameter, I_{MAX}, defines the upper limit on the number of iterations that can be run on any codeword. This limit prevents the decoder from wasting too much time on a codeword that is unlikely to converge. I_{MAX} may be determined based on simulations or tests of the decoder using a particular channel and set of system parameters.

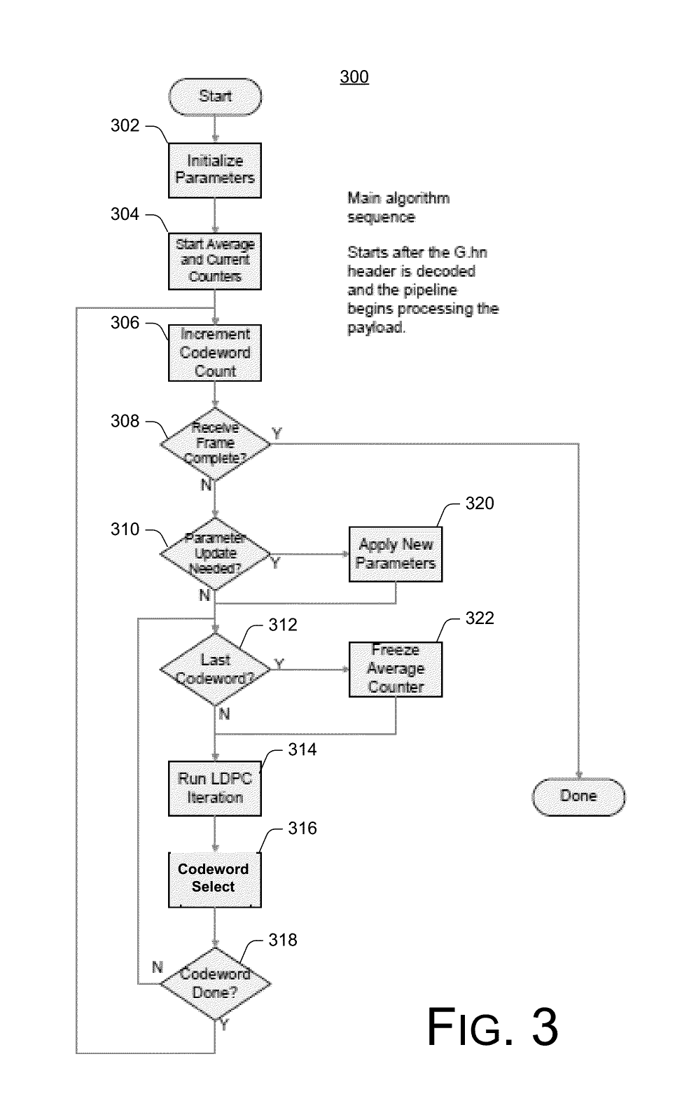

The example algorithm may also be explained by way of flowcharts, as shown in FIGS. 3-5.

FIG. 3 illustrates a process 300 of an example algorithm in the context of G.hn in accordance with an embodiment of the present disclosure. The process 300 may be implemented in the transceiver 100 of FIG. 1, and may be executed after the G.hn header is decoded and the receive pipeline of the transceiver 100 begins processing the payload of a received frame. The following description of process 300 refers to FIG. 3.

At 302, the algorithm initializes parameters and/or variables. For example, the algorithm may initialize the working variables as follows: CNT_{AVE}=CL_{CW}, CNT_{Slack}=CL_{INIT}, CW_{AVE}=0 and CW_{CUR}=0.

At 304, the algorithm starts average and current counters. For example, the algorithm may start the codeword counter CW_{CUR} as well as the clock counters CNT_{AVE} and CNT_{Slack}.

At 306, the algorithm increments codeword count. For example, the current codeword counter CW_{CUR} is incremented.

At 308, the algorithm determines whether the receiving of a frame by the transceiver 100 has been completed. If the receiving of the frame has been completed, the process 300 stops; otherwise, the process 300 proceeds to 310.

At 310, the algorithm determines whether parameter update is necessary. If it is determined that the update of one or more parameters is necessary, the process 300 proceeds to 320, at which point any new parameter update is applied, and then proceeds to 312. If it is determined that no parameter update is necessary, the process 300 directly proceeds from 310 to 312.

At 312, the algorithm determines whether the particular codeword currently being processed is the last codeword. If it is determined that the particular codeword is the last codeword, then the process 300 proceeds to 322 to freeze the average counter, e.g., by freezing the counter CW_{AVE}, and then proceeds to 314. If it is determined that no parameter update is necessary, the process 300 directly proceeds from 312 to 314.

At 314, the algorithm runs an LDPC iteration.

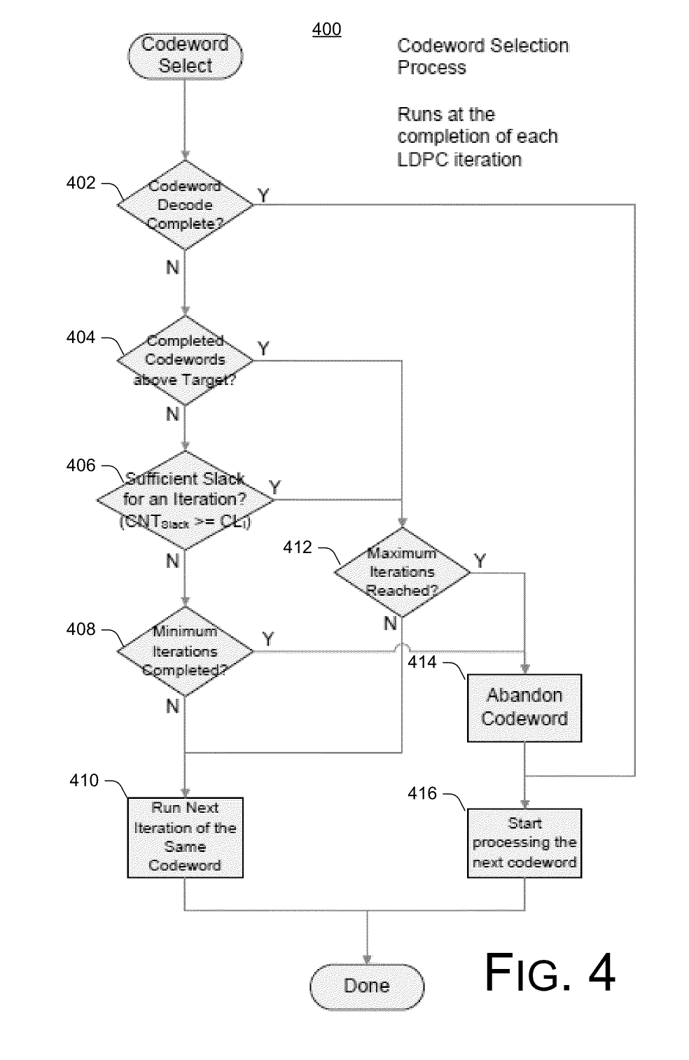

At 316, the algorithm performs codeword selection. For example, the algorithm performs process 400, as shown in FIG. 4 and described below, for codeword selection.

At 318, the algorithm determines whether the processing of the current codeword is completed (e.g., the codeword was successfully decoded or it was abandoned). If it is determined that the processing of the codeword is completed, the process 300 proceeds to 306; otherwise, the process 300 proceeds to 312.

FIG. 4 illustrates a process 400 of codeword selection of the example algorithm in accordance with an embodiment of the present disclosure. The process 400 may be executed at the completion of each LDPC iteration. The following description of process 400 refers to FIG. 4.

At 402, the algorithm determines whether the decoding of a given codeword is complete. If it is determined that the decoding of the codeword is complete, the process 400 proceeds to 416, at which point the process 400 starts processing the next codeword in the frame; otherwise, the process 400 proceeds to 404.

At 404, the algorithm determines whether the current count of processed codewords is greater than the number of codewords that should have been processed. If it is determined that the current count of processed codewords, e.g., CW_{CUR}, is greater than the number of codewords that should have been processed, e.g., CW_{AVE}, the process 400 proceeds to 412; otherwise, the process 400 proceeds to 406.

At 406, the algorithm determines whether there is sufficient slack for an iteration, e.g., whether it is true that CNT_{Slack} is greater than or equal to CL_{I}. If it is determined that there is sufficient slack for an iteration, the process 400 proceeds to 412; otherwise, the process 400 proceeds to 408.

At 408, the algorithm determines whether a minimum number of iterations have been completed, e.g., I_{CUR}>=I_{MIN}. If the determination is positive, the process 400 proceeds to 414; otherwise, the process 400 proceeds to 410. Alternatively, the LDPC decoder or another algorithm may decide to abandon the codeword before I_{MIN} iterations are carried out. In such case the process 400 also proceeds to 414.

At 410, the algorithm selects the next iteration of the same codeword to be ran next.

At 412, the algorithm determines whether a maximum number of iterations have been reached, e.g., I_{CUR}=I_{MAX}. If the determination is negative, the process 400 proceeds to 410; otherwise, the process 400 proceeds to 414.

At 414, the algorithm abandons the codeword. For example, if the codeword fails to converge after the maximum number of iterations have been completed, the algorithm determines that there is an uncorrectable error and stops trying to decode the codeword.

At 416, the algorithm selects the first iteration of the next codeword in the received frame to be processed next.

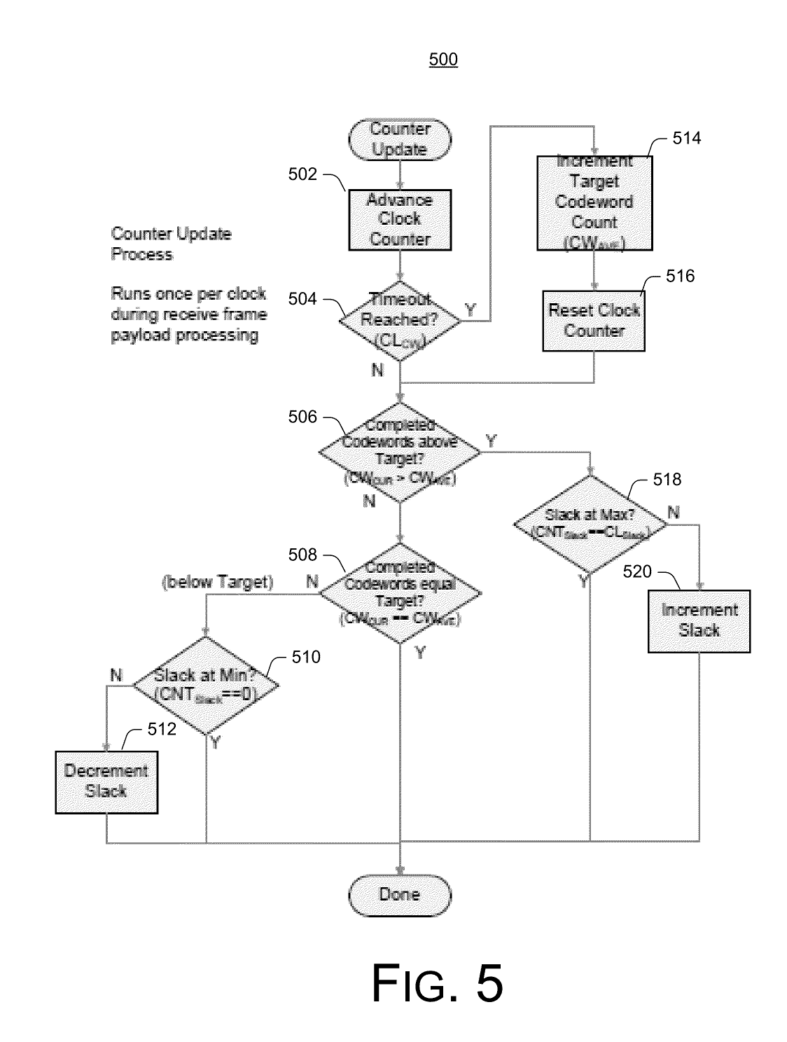

FIG. 5 illustrates a process 500 of counter update of the example algorithm in accordance with an embodiment of the present disclosure. The algorithm may run counter update once per clock during receive frame payload processing. The following description of process 500 refers to FIG. 5.

At 502, the algorithm advances clock counter.

At 504, the algorithm determines whether timeout has been reached. If it is determined that timeout, e.g., CL_{CW}, has been reached, the process 500 proceeds to 514; otherwise, the process 500 proceeds to 506.

At 506, the algorithm determines whether the current count of processed codewords is greater than the number of codewords that should have been processed. If it is determined that the current count of processed codewords, e.g., CW_{CUR}, is greater than the number of codewords that should have been processed, e.g., CW_{AVE}, the process 500 proceeds to 518; otherwise, the process 500 proceeds to 508.

At 508, the algorithm determines whether the current count of processed codewords is equal to the number of codewords that should have been processed. If it is determined that the current count of processed codewords, e.g., CW_{CUR}, is equal to the number of codewords that should have been processed, e.g., CW_{AVE}, the process 500 ends; otherwise, the process 500 proceeds to 510.

At 510, the algorithm determines whether the clock counter for slack is at the minimum, e.g., CNT_{Slack}=0. If it is determined that the clock counter for slack is at the minimum, the process 500 ends; otherwise, the process 500 proceeds to 512.

At 512, the algorithm decrements the clock counter for slack, e.g., CNT_{Slack}=CNT_{Slack}−1.

At 514, the algorithm increments target codeword count. For example, the algorithm increments CW_{AVE}.

At 516, the algorithm resets the clock counter.

At 518, the algorithm determines whether the slack is at the maximum. For example, the algorithm determines whether CNT_{Slack} is equal to CL_{Slack}. If it is determined that the slack is at the maximum, the process 500 ends; otherwise, the process 500 proceeds to 520.

At 520, the algorithm increments the clock counter for slack, e.g., CNT_{Slack}=CNT_{Slack}+1.

### Example Pseudo Code

An example pseudo code that executes the above-described algorithm is described below. At the beginning of the first payload symbol (after ACE if present) the above parameters (CL_{CW}, I_{MIN}, I_{MAX}, CL_{I}, I_{Slack}, CL_{Slack} and CL_{INIT}) are calculated. Then, the working variables are initialized as follows:
CNT_{AVE}=CL_{CW}
CNT_{Slack}=CL_{INIT}
CW_{AVE}=0
CW_{CUR}=0

The following example pseudo code describes an operation of the algorithm for calculations.

```
For every system clock after initialization
  // Track the time for an average codeword
  CNT_{AVE} = CNT_{AVE} − 1
  If (CNT_{AVE} == 0)
{
    CNT_{AVE} = CL_{CW}
    CW_{AVE} = CW_{AVE} + 1
}
  // Track the number of slack cycles
```

| | |
|---|---|
| If (CW_{CUR} > CW_{AVE}) | // Ahead of codeword target, add more |

slack

| | |
|---|---|
| If (CNT_{Slack} == CL_{Slack}) | // Slack counter maxes out at CL_{Slack} |

```
      CNT_{Slack} = CNT_{Slack}
    Else
      CNT_{Slack} = CNT_{Slack} + 1
  Else if (CW_{CUR} == CW_{AVE}) // Matching the codeword target, maintain
slack
    CNT_{Slack} = CNT_{Slack}
  Else (CW_{CUR} < CW_{AVE})  // Behind the codeword target, remove slack
    If (CNT_{Slack} == 0) CNT_{Slack} = CNT_{Slack}
    Else CNT_{Slack} = CNT_{Slack} − 1
After every LDPC decoder iteration
  If (codeword decoded)
    CW_{CUR} = CW_{CUR} + 1
    Continue to next codeword
  Else
    If (CW_{CUR} > CW_{AVE}) // Ahead of or matching codeword target
      If (I_{CUR} < I_{MAX}) Run another iteration
      Else Abandon codeword and go to next codeword
    If (CW_{CUR} <= CW_{AVE}) // Behind codeword target
      If (CNT_{Slack} >= CL_{I}) // Is there enough slack for another iteration?
        If (I_{CUR} < I_{MAX}) Run another iteration
        Else Abandon codeword and go to next codeword
      Else
        If (I_{CUR} < I_{MIN}) Run another iteration
        Else Abandon codeword and go to next codeword
```

When the last codeword of a frame is started in the LDPC decoder, the algorithm may set the value of certain variables as follows:
CNT_{AVE}=0//Stop the average counter
CW_{AVE}=CW_{AVE} //Freeze the average

The calculations shown in the pseudo code above are performed on the last codeword which would be given the remaining slack or I_{MAX} iterations, whichever is less.

As an additional optimization, the last codewords of a frame may be allowed to run for an extended time when the LDPC decoder runtime is limited by the size of the RX FIFO instead of the IFG. A separate iteration parameter is defined for this case: I_{LAST}. After the last OFDM symbol is received in the time domain (e.g., the RX FIFO is no longer collecting new samples), all remaining codewords may be allowed to run for I_{LAST} iterations, regardless of the slack.

### Example Enhancements

### Example Enhancement 1

When an impulse noise event occurs, it may be possible to determine that one or more codewords are unlikely to be correctable. For example, the masked or unused subcarriers could be used to detect impulse noise events by determining the total amount of error that is received in the known data for all masked tones. Likewise, the error in the data carrying tones could be accumulated to infer if an impulse noise event had likely occurred. Using this information the LDPC input could be indicated as erased and likely uncorrectable. If a codeword is indicated as erased the algorithm could take that into account and avoid wasting time on trying to process the codeword. It is likely that such codewords would not be able to be decoded and would require retransmission. To compensate, the algorithm could recalculate the CL_{CW} and other parameters based on fewer codewords needing to be decoded.

### Example Enhancement 2

In the preceding discussion the algorithm is discussed using a system clock to measure the passage of time. However, any timing reference could be used as long as it has sufficient accuracy. As an example, the G.hn network timing reference (NTR) could be used. The NTR measures the passage of time based on a network-wide timing reference. This method allows the algorithm to work independently of the speed of the system clock and automatically adjust for network timing. It is noteworthy that the NTR is one possible alternative timing reference, among others. The algorithm attempts to compensate for both the RX FIFO and IFG requirements in one set of parameters. Although this would be effective in many cases, in other cases it would be more optimal to allow the parameters to be reset to new values when some codewords remain to be processed. On a long frame, this method would allow the algorithm to use one set of parameters initially for avoiding RX FIFO overflow and then another set at the end to ensure IFG or to provide additional time when IFG is not a concern. The second set of parameters could be precalculated and programmed to be applied after a certain number of codewords have been processed.

Example enhancements 1 and 2 discuss times when it may be beneficial to recalculate the algorithm parameters, in particular the target processing rate, CL_{CW}, maximum slack, CL_{Slack}, and the iteration limits, I_{MIN} and I_{MAX}. Other events could trigger a parameter update and the parameters could be updated for every codeword if necessary. However, since parameter calculations can be more complex than the algorithm for tracking progress, it is expected that parameter updates would not occur often. The algorithm would perform well with no parameter updates in most cases.

### Example Process

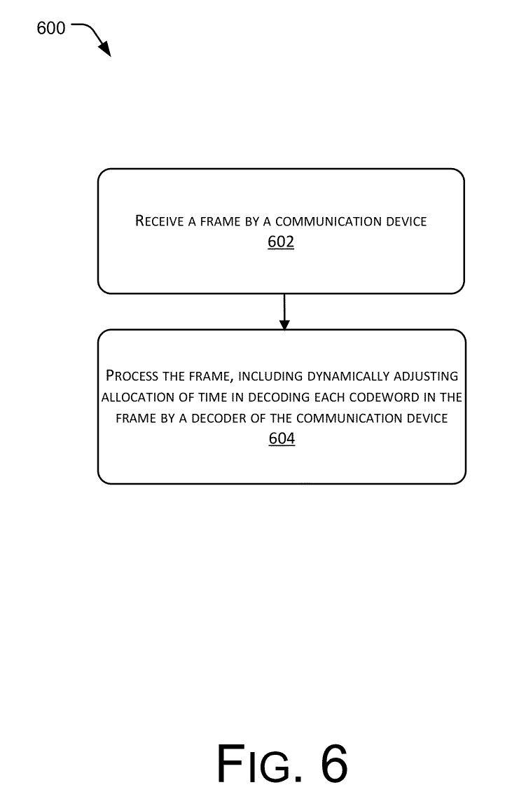

FIG. 6 illustrates a process 600 of efficient FEC decoder scheduling and receiver flow pipeline control in accordance with an embodiment of the present disclosure.

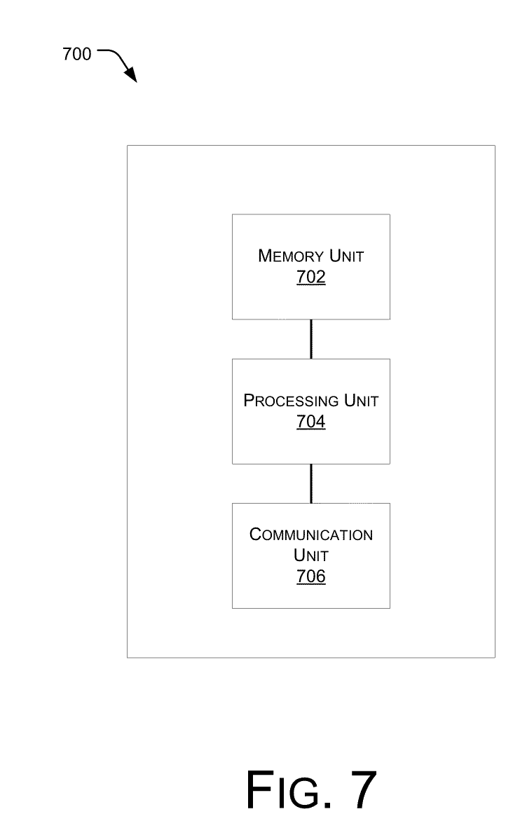

Example process 600 includes one or more operations, actions, or functions as illustrated by one or more of blocks 602 and 604. Although illustrated as discrete blocks, various blocks may be divided into additional blocks, combined into fewer blocks, or eliminated, depending on the desired implementation. Process 600 may be implemented in one or more scenarios as depicted in one or more of FIGS. 1 and 7. Further, process 600 may be implemented by software, firmware, hardware, or any combination thereof in an integrated-circuit processor, a chipset or a communication device. For illustrative purposes, the operations described below are performed by a communication device such as transceiver 100 of FIG. 1. Process 600 may begin at block 602.

At 602, the communication device may receive a frame.

At 604, the communication device may process the frame by dynamically adjusting allocation of time for decoding each codeword in the frame by a decoder of the communication device.

In one embodiment, in dynamically adjusting allocation of time for decoding each codeword in the frame, the communication device may calculate a target number of iterations that cannot be exceeded by the decoder in decoding each codeword. For example, the communication device may calculate the following: an average amount of time that can be allowed by the decoder in decoding each codeword, a minimum amount of time that must be allowed by the decoder in decoding each codeword, and a maximum amount of time that cannot be exceeded by the decoder in decoding each codeword

In one embodiment, in dynamically adjusting allocation of time for decoding each codeword in the frame, the communication device may track a number of iterations by the decoder in decoding a first codeword in the frame. For example, the communication device may track, during processing of the frame, a number of codewords processed by the decoder as well as a target number of codewords that would be processed if the average codeword processing time were maintained.

In one embodiment, in dynamically adjusting allocation of time for decoding each codeword in the frame, the communication device may determine whether the number of codewords processed by the decoder is above the target number of codewords.

In one embodiment, in response to determining that the number of codewords processed by the decoder is above the target number of codewords, the communication device may determine whether an amount of time used by the decoder in decoding a current codeword equals a maximum amount of time that cannot be exceeded by the decoder in decoding each codeword.

In one embodiment, in response to determining that the amount of time used by the decoder in decoding a current codeword has reached the maximum amount of time, the communication device may abandon the current codeword and process a next codeword in the frame.

In one embodiment, in response to determining that the amount of time used by the decoder in decoding the current codeword has not reached the maximum amount of time and enough time remains to run a decoder iteration, the communication device may enable the decoder to perform a next iteration on the current codeword.

In one embodiment, in response to determining that the number of codewords processed by the decoder is not above the target number of codewords, the communication device may determine whether there is sufficient extra time to allow for one or more additional iterations by the decoder for the current codeword.

In one embodiment, in determining whether there is sufficient extra time, the communication device may track an amount of extra time to allow for one or more additional iterations by the decoder for each codeword based at least in part on a number of clocks per iteration for decoding a codeword of a given size and a clock counter used in tracking the slack.

In one embodiment, in response to determining that there is sufficient extra time to allow for one or more additional iterations by the decoder for the first codeword, the communication device may determine whether the time used by the decoder in decoding the current codeword equals the maximum amount of time that cannot be exceeded by the decoder in decoding each codeword.

In one embodiment, in response to determining that the time used by the decoder in decoding the current codeword has reached the maximum amount of time, the communication device may abandon the current codeword and process a next codeword in the frame.

In one embodiment, in response to determining that the amount of time used by the decoder in decoding a current codeword has not reached the maximum allowed time, the communication device may enable the decoder to perform a next iteration on the current codeword.

In one embodiment, in response to determining that there is not sufficient extra time to allow for one or more additional iterations by the decoder for the current codeword, the communication device may determine whether a minimum amount of time has been consumed by the decoder in decoding the current codeword.

In one embodiment, in response to determining that the minimum amount of time has been consumed by the decoder in decoding the current codeword, the communication device may abandon the current codeword and process a next codeword in the frame.

In one embodiment, in response to determining that the minimum amount of time has not been consumed by the decoder in decoding the first codeword, the communication device may enable the decoder to perform a next iteration on the first codeword.

In one embodiment, the decoder comprises a LDPC decoder.

In one embodiment, a decoder time is tracked based on iterations of the LDPC decoder.

In one embodiment, the average, minimum, and maximum times are recalculated at some points during processing of the frame.

### Example Device

FIG. 7 illustrates a device 700 configured to perform efficient FEC decoder scheduling and receiver flow pipeline control in accordance with an embodiment of the present disclosure. In particular, FIG. 7 illustrates components of a communication device 700 that is capable of performing operations in accordance with the present disclosure, including executing the algorithm and pseudo code described above, including processes 300, 400, 500, 600 and any variations thereof. Communication device 700 may be an IC chip or a chipset, for example. In one embodiment, device 700 may be implemented as the transceiver 100. For example, analog front end block of transceiver 100 may correspond to the communication unit 706 of device 700 while some or all of the remaining components of transceiver 100 may correspond to the processing unit 704 of device 700.

As shown in FIG. 7, the communication device 700 comprises a memory unit 702, a processing unit 704, and a communication unit 706. The memory unit 702 is configured to store data, one or more sets of instructions, or both data and instructions. The processing unit 704 is configured to execute the one or more sets of instructions stored in the memory unit 702. The communication unit 706 is configured to transmit data (e.g., frames with codewords) and receive data under the command of the processing unit 704. Upon executing the one or more sets of instructions stored in the memory unit 702, the processing unit 704 executes one or more of processes 300, 400, 500 and 600, and any variations thereof.

### ADDITIONAL AND ALTERNATIVE IMPLEMENTATION NOTES

The above-described techniques pertain to efficient FEC decoder scheduling and receiver pipeline flow control. Although the techniques have been described in language specific to structural features and/or methodological acts, it is to be understood that the appended claims are not necessarily limited to the specific features or acts described. Rather, the specific features and acts are disclosed as example forms of implementing such techniques. Those skilled in the art may make derivations and/or modifications of any of the disclosed embodiments or any variations thereof, and such derivations and modifications are still within the scope of the present disclosure.

In the above description of example implementations, for purposes of explanation, specific numbers, materials configurations, and other details are set forth in order to better explain the invention, as claimed. However, it would be apparent to one skilled in the art that the claimed invention may be practiced using different details than the example ones described herein. In other instances, well-known features are omitted or simplified to clarify the description of the example implementations.

The inventor intends the described embodiments to be primarily examples. The inventor does not intend these embodiments to limit the scope of the appended claims. Rather, the inventor has contemplated that the claimed invention might also be embodied and implemented in other ways, in conjunction with other present or future technologies.

Moreover, the word “example” is used herein to mean serving as an example, instance, or illustration. Any aspect or design described herein as “example” is not necessarily to be construed as preferred or advantageous over other aspects or designs. Rather, use of the word example is intended to present concepts and techniques in a concrete fashion. The term “techniques,” for instance, may refer to one or more devices, apparatuses, systems, methods, articles of manufacture, and/or computer-readable instructions as indicated by the context described herein.

As used in the present disclosure, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more,” unless specified otherwise or clear from context to be directed to a singular form.

What is claimed is:

1. A method, comprising:
receiving, by a communication device, a frame; and
processing the frame by the communication device, the processing comprising:
dynamically adjusting allocation of time for decoding each codeword in the frame by a decoder of the communication device.

2. The method of claim 1, wherein the dynamically adjusting allocation of time for decoding each codeword in the frame comprises:
calculating:
an average amount of time that can be allowed by the decoder in decoding each codeword,
a minimum amount of time that must be allowed by the decoder in decoding each codeword, and
a maximum amount of time that cannot be exceeded by the decoder in decoding each codeword.

3. The method of claim 2, wherein the dynamically adjusting allocation of time for decoding each codeword in the frame further comprises:
tracking, during processing of the frame, a number of codewords processed by the decoder; and a target number of codewords that would be processed if the average codeword processing time were maintained.

4. The method of claim 3, wherein the dynamically adjusting allocation of time for decoding each codeword in the frame further comprises:
determining whether the number of codewords processed by the decoder is above the target number of codewords.

5. The method of claim 4, wherein the dynamically adjusting allocation of time for decoding each codeword in the frame further comprises:
in response to determining that the number of codewords processed by the decoder is above the target number of codewords, determining whether an amount of time used by the decoder in decoding a current codeword equals a maximum amount of time that cannot be exceeded by the decoder in decoding each codeword.

6. The method of claim 5, wherein the dynamically adjusting allocation of time for decoding each codeword in the frame further comprises:
in response to determining that the amount of time used by the decoder in decoding a current codeword has reached the maximum amount of time:
abandoning the current codeword; and
processing a next codeword in the frame.

7. The method of claim 5, wherein the dynamically adjusting allocation of time for decoding each codeword in the frame further comprises:
in response to determining that the amount of time used by the decoder in decoding the current codeword has not reached the maximum amount of time, enabling the decoder to perform a next iteration on the current codeword.

8. The method of claim 4, wherein the dynamically adjusting allocation of time for decoding each codeword in the frame further comprises:
in response to determining that the number of codewords processed by the decoder is not above the target number of codewords, determining whether there is sufficient extra time to allow for one or more additional iterations by the decoder for the current codeword.

9. The method of claim 8, wherein the determining whether there is sufficient extra time comprises:
tracking an amount of extra time to allow for one or more additional iterations by the decoder for each codeword based at least in part on a number of clocks per iteration for decoding a codeword of a given size and a clock counter used in tracking the slack.

10. The method of claim 8, wherein the dynamically adjusting allocation of time for decoding each codeword in the frame further comprises:
in response to determining that there is sufficient extra time to allow for one or more additional iterations by the decoder for the first codeword, determining whether the time used by the decoder in decoding the current codeword equals the maximum amount of time that cannot be exceeded by the decoder in decoding each codeword.

11. The method of claim 10, wherein the dynamically adjusting allocation of time for decoding each codeword in the frame further comprises:
in response to determining that the time used by the decoder in decoding the current codeword has reached the maximum amount of time:
abandoning the current codeword; and
processing a next codeword in the frame.

12. The method of claim 10, wherein the dynamically adjusting allocation of time for decoding each codeword in the frame further comprises:
in response to determining that the amount of time used by the decoder in decoding a current codeword has not reached the maximum allowed time, enabling the decoder to perform a next iteration on the current codeword.

13. The method of claim 8, wherein the dynamically adjusting allocation of time for decoding each codeword in the frame further comprises:
in response to determining that there is not sufficient extra time to allow for one or more additional iterations by the decoder for the current codeword, determining whether a minimum amount of time has been consumed by the decoder in decoding the current codeword.

14. The method of claim 13, wherein the dynamically adjusting allocation of time for decoding each codeword in the frame further comprises:
in response to determining that the minimum amount of time has been consumed by the decoder in decoding the current codeword:
abandoning the current codeword; and
processing a next codeword in the frame.

15. The method of claim 13, wherein the dynamically adjusting allocation of time for decoding each codeword in the frame further comprises:
in response to determining that the minimum amount of time has not been consumed by the decoder in decoding the first codeword, enabling the decoder to perform a next iteration on the first codeword.

16. The method of claim 1, wherein the decoder comprises a low density parity check (LDPC) decoder.

17. The method of claim 16, wherein a decoder time is tracked based on iterations of the LDPC decoder.

18. The method of claim 2, wherein the average, minimum, and maximum times are recalculated at some points during processing of the frame.

19. A device, comprising:
a memory unit configured to store data, a set of instructions, or a combination thereof;
a communication unit configured to receive a frame; and
a processing unit coupled to the memory unit and the communication unit, the processing unit configured to process the frame by dynamically adjusting allocation of time for decoding each codeword in the frame.

20. The device of claim 19, wherein in dynamically adjusting allocation of time for decoding each codeword in the frame, the processing unit is configured to perform operations comprising:
calculating:
an average amount of time that can be allowed by the processing unit in decoding each codeword,
a minimum amount of time that must be allowed by the processing unit in decoding each codeword, and
a maximum amount of time that cannot be exceeded by the processing unit in decoding each codeword;
tracking, during processing of the frame, a number of codewords processed by the processing unit and a target number of codewords that would be processed if the average codeword processing time were maintained; and
determining whether the number of codewords processed by the processing unit is above the target number of codewords.

21. The device of claim 20, wherein in dynamically adjusting allocation of time for decoding each codeword in the frame, the processing unit is further configured to perform operations comprising:
in response to determining that the number of codewords processed by the decoder is above the target number of codewords, determining whether an amount of time used by the processing unit in decoding a current codeword equals a maximum amount of time that cannot be exceeded by the processing unit in decoding each codeword;
in response to determining that the amount of time used by the processing unit in decoding a current codeword has reached the maximum amount of time:
abandoning the current codeword; and
processing a next codeword in the frame; and
in response to determining that the amount of time used by the decoder in decoding the current codeword has not reached the maximum amount of time, enabling the processing unit to perform a next iteration on the current codeword.

22. The device of claim 20, wherein in dynamically adjusting allocation of time for decoding each codeword in the frame, the processing unit is further configured to perform operations comprising:
in response to determining that the number of codewords processed by the processing unit is not above the target number of codewords, determining whether there is sufficient extra time to allow for one or more additional iterations by the processing unit for the current codeword;
tracking an amount of extra time to allow for one or more additional iterations by the processing unit for each codeword based at least in part on a number of clocks per iteration for decoding a codeword of a given size and a clock counter used in tracking the extra time;
in response to determining that there is sufficient extra time to allow for one or more additional iterations by the processing unit for the current codeword, determining whether the time used by the processing unit in decoding the current codeword equals the maximum amount of time that cannot be exceeded by the processing unit in decoding each codeword;
in response to determining that the time used by the processing unit in decoding the current codeword has reached the maximum amount of time:
abandoning the current codeword; and
processing a next codeword in the frame;
in response to determining that the time used by the processing unit in decoding the current codeword has not reached the maximum amount of time, performing a next iteration on the current codeword;
in response to determining that there is not sufficient extra time to allow for one or more additional iterations by the processing unit for the current codeword, determining whether a minimum number of iterations has been performed by the processing unit in decoding the first codeword;
in response to determining that the minimum amount of time has been consumed by the processing unit in decoding the current codeword:
abandoning the current codeword; and
processing a next codeword in the frame; and
in response to determining that the minimum amount of time has not been consumed by the processing unit in decoding the current codeword, performing a next iteration on the current codeword.
